(19) United States
(12) Patent Application Publication
(10) Pub. No.: US 2006/0024450 A1
(43) Pub. Date: Feb. 2, 2006

(54) Method for increasing the work function of ITO film under an excimer laser exposure treatment

(76) Inventors: Yow-Jon Lin, Jhuci Township (TW); Chou-Wei Hsu, Hsinchu City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/190,961

(22) Filed: Jul. 28, 2005

(30) Foreign Application Priority Data
Aug. 2, 2004 (TW) 93123145

(51) Int. Cl. B05D 3/00; B06B 1/00

(52) U.S. Cl. 427/554; 427/600

(57) ABSTRACT

The present invention relates to a method for increasing the work function of the indium-tin-oxide (ITO) film under an excimer laser exposure treatment. The range of the excimer laser energy is between tens and hundreds mJ/cm², the frequency range is between zero and one hundred Hz, and exposure time is between five minutes to tens hours. It, therefore, can increase the work function of the indium-tin-oxide (ITO) film.

### FIELD OF THE INVENTION

The invention relates to the component manufacture in the optical field. More particularly, it relates a method for increasing the work function of the indium-tin-oxide (ITO) film under an excimer laser exposure treatment.

### BACKGROUND OF THE RELATED ART

Indium-tin-oxide (ITO) film is widely used in various optical components recently, such as solar batteries, various display panels, light emitting diodes (LEDs), and organic light emitting diodes (OLEDs). Since ITO has higher electrical conductivity, and transparency, ITO becomes a very important material in various optical components. The latest research found that if ITO has higher work function, and it can be applicable to the positive of OLED manufacture. As can be seen from FIG. 5, it is a basic OLED structure. It uses ITO conductive substrate as the positive, and uses the material having lower work function as the negative, such as Al, Mg, and Ca. The OLED layer is embedded by the positive and the negative. The OLED layer includes hole-transporting layer (HTL), emitting layer, and electron-hole layer (EHL).

In the operational process of the component, the hole in the positive and the electron in the negative are formed as a said electron-hole recombination. As shown in FIG. 6, the position of electron status is from high energy of ground state returning to low energy of steady state. The difference of the energy is released by photon and heat, respectively. Then, the organic material is emitted to produce the light. The key of the light emitting performance is mainly from the structure of the organic layer, and the negative and positive designs.

Since ITO has higher work function, it can form a lower barrier in the between of ITO and HTL. Further, the hole is easy to be injected and can occupy the higher molecular orbital in OLED. Then, it can increase the light emitting performance in OLED and decrease the operational voltage of the component. Please refer to FIG. 6, the arrow here points out the barrier forming in the between of ITO and HTL.

The methods for increasing the work function in ITO surface nowadays have: (a) inductively coupled plasma treatment technique under the oxygen condition for ITO surface treatment. It can increase the surface work function of ITO film. (b) ITO film deposited under strong acid or strong alkalis liquid for ITO surface treatment. It can change the resistance and the surface work function of ITO film.

Although the above mentioned methods can increase the surface work function ITO film, they have complicated treatment processes, and chemical pollution problems. These problems necessarily have to be improved.

### SUMMARY OF THE INVENTION

In order to solve the above mentioned problems, the main object of the present invention is to provide a method for effectively increasing the work function of the indium-tin-oxide (ITO) film under an excimer laser exposure treatment.

Further, in order to achieve the above mentioned purpose, the method for increasing the work function of the indium-tin-oxide (ITO) film under an excimer laser exposure treatment in the present invention uses the excimer laser to expose ITO film, and increases its surface work function. The range of the excimer laser energy is between tens and hundreds mJ/cm², the frequency range is between zero and one hundred Hz, and exposure time is between five minutes to tens hours.

As a result, the present invention can be applicable to OLED and various display panels. It is extremely helpful to the positive of the surface treatment in the optical components, and can effectively improve component performance and decrease the operational voltage of the component.

### SIMPLE DESCRIPTION OF THE DRAWINGS

FIG. 1 is a flow chart of the method in the present invention;

FIG. 2 shows the relationship between the resistance and the laser exposure time after ITO film sample under different excimer laser exposure time;

FIG. 3 shows the valence spectroscopy after ITO film sample under different excimer laser exposure time;

FIG. 4 shows Ols spectroscopy after ITO film sample under different excimer laser exposure time;

FIG. 5 shows a basic OLED device structure.

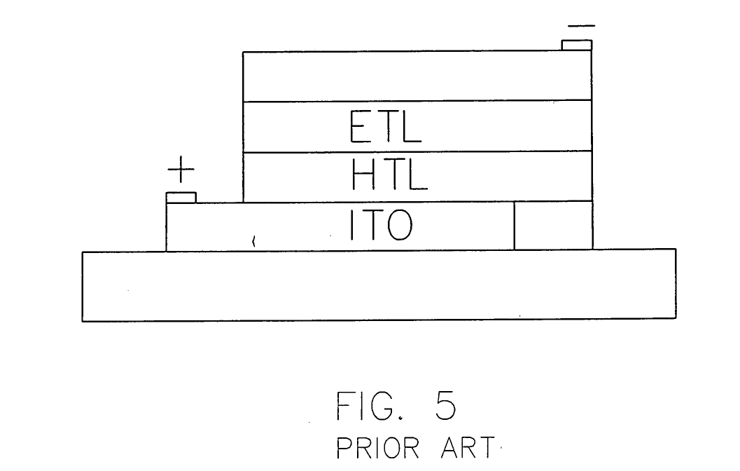

FIG. 6 shows the electron-hole recombination in the emitting layer forming from the hole in the positive and the electron in the negative during operational process of the component.

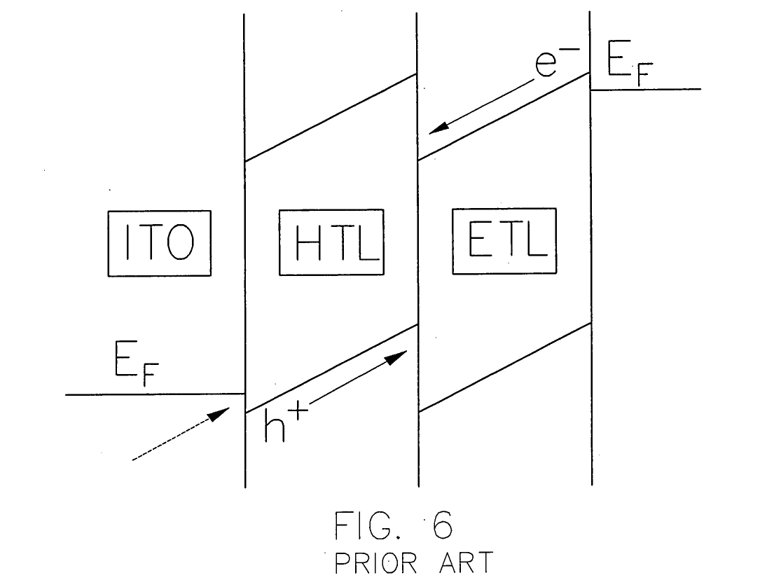

### DETAILED DESCRIPTION OF THE PREFERRED EMBODIMENTS

Additional features and advantages of the invention will be set forth in the detailed description which follows, and in part will be readily apparent to those skilled in the art from the description or recognized by practicing the invention as described in the written description and claims hereof, as well as the appended drawings.

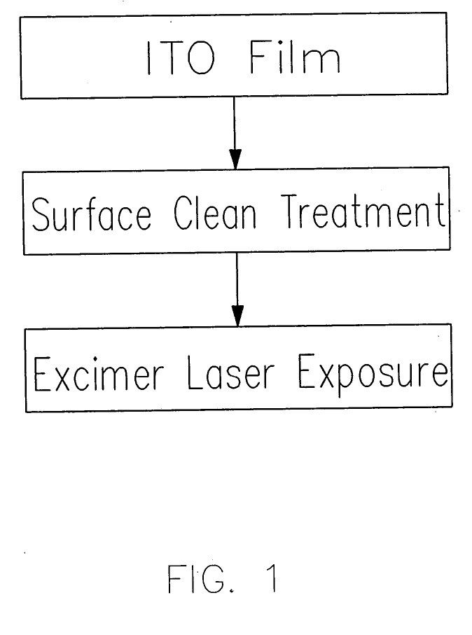

Please refer to FIG. 1 to FIG. 4. The figures are the preferred embodiments for the present invention.

The preferred embodiments in the present invention use the ITO film sample grown on the substrate which is purchasing from Taichung Wintek Corporation. The thickness of the ITO film sample is approximately 26 nm. The sheet resistance is 71.38O/□.

First, ITO sample is deposited in acetone, and cleaned by water-jacket ultrasonic vibration for three minutes. Then, ITO is deposited in the deionized water for three minutes. Finally, it is dried by nitrogen gun. The sample sheets are divided to three sets for different experiments. The first set (Sample 1) does not take any treatment, and the second set (Sample B) and the third set (Sample C) are directly exposed under the excimer laser in the air. The range of said excimer laser is between tens and hundreds mJ/cm², the frequency range is between 0 and 100 Hz, and the exposure time are 10 minutes and 15 minutes, respectively. The preferred embodiment in the present invention uses KrF excimer laser with 250 nm of wavelength, 10 minutes and 15 minutes of the exposure time, respectively, 26 mJ/cm² of incident laser energy, 50 Hz of frequency, and 50 ns of pulse duration. Further, 4-point probe and X-ray photoelectron spectroscopy (XPS) are used to measure three sets of samples.

According to the result of 4-point probe measurement measuring in the same sample ( i.e. the same sheet sample is exposed under KrF excimer laser for 5, 10, and 15 minutes, respectively), it can be found that the resistance (R) of ITO sample is increased following the increased exposure time. The resistance value can be directly derived from Ohm law. According to Awint and Bohn's papers, when ITO samples are deposited under chemical liquid which is with different pH values, the resistance value of ITO is changed. This surface treatment theory is integrated from the relationship of the thicknesses of n-type depletion layer and the observed resistance in ITO film (approximately 15-30 nm). The experimental result shows that when the thickness of n-type depletion (the effective thickness of ITO sample is decreased) becomes thicker, the observed resistance becomes larger. Further, when ITO sample is deposed in acid or alkalis liquid, the voltage change can be caused by surface carrier and dipole absorption in the surface. The relationship between the resistance (ΔR) and the effective thickness (Δteff) in ITO sample shows as the following:

$$\frac{Δ R}{{R}_{0}} \sim \frac{ρ l}{Δ {t}_{eff} w}$$

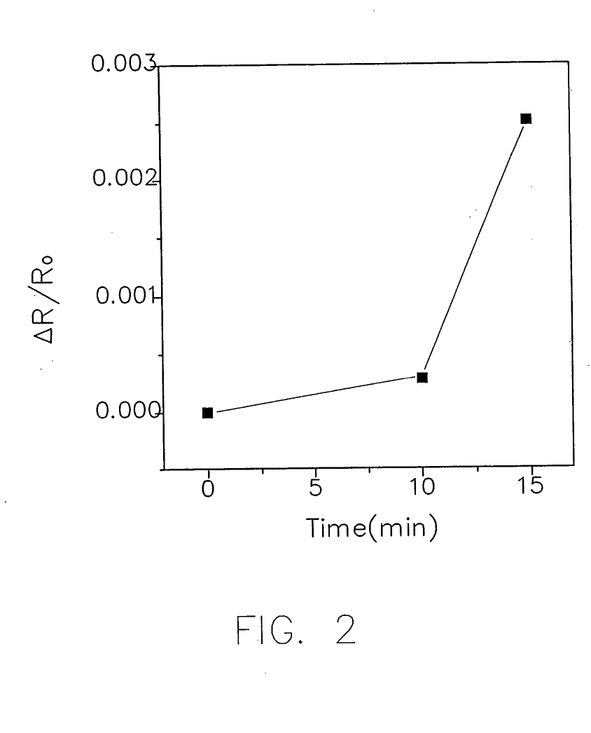

R₀ is resistance in the condition of ITO sample without any treatment, ρ is resistivity, l is film length, and w is film width. In the present experiment, the resistance of ITO sample is increased after the excimer laser exposure. In other word, the resistance of ITO sample is increased following the increased laser exposure time, please refer to FIG. 2. This result shows that the thickness of the depletion layer is increased, the effective thickness (teff) is decreased, and the resistance and the surface work function are increased when ITO sample is under excimer laser exposure.

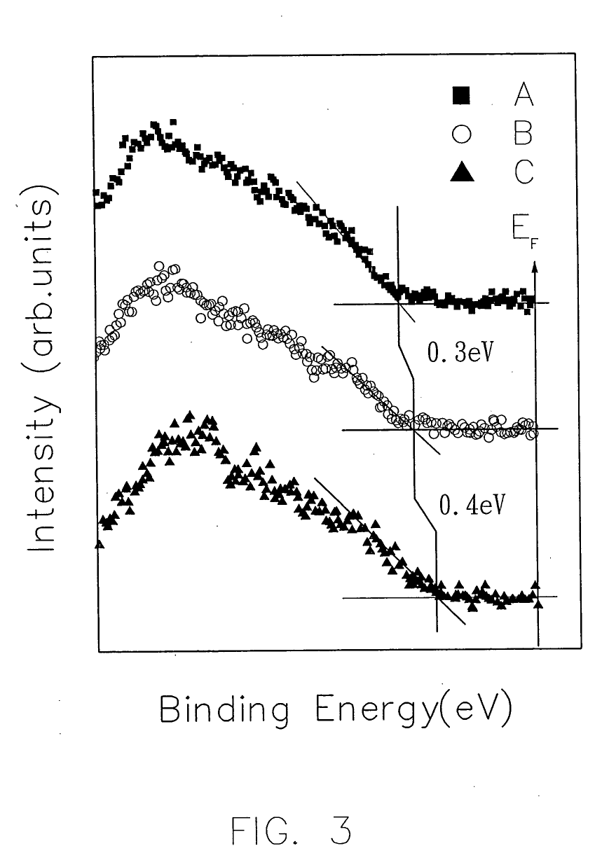

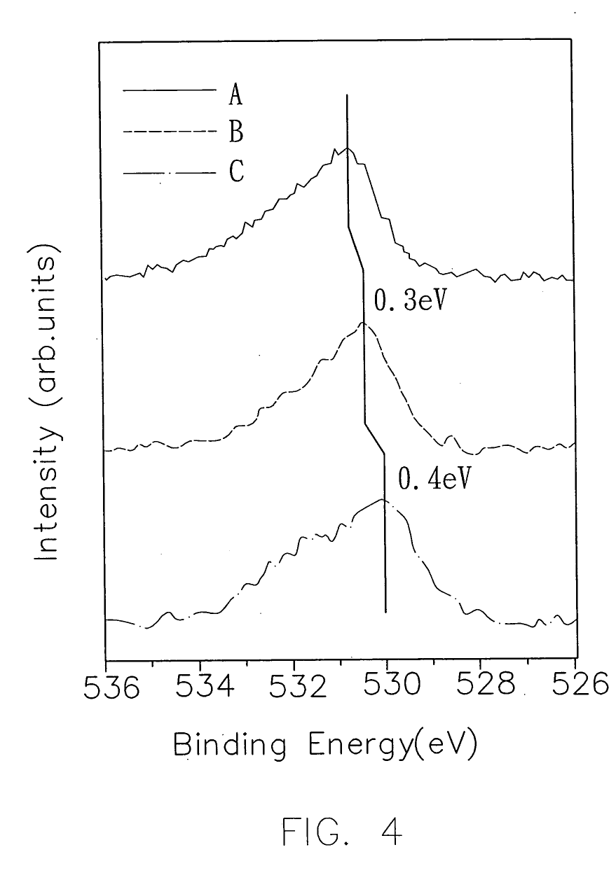

In order to obtain the chemical change on the surface after ITO sample under laser exposure, the present experiment uses X-ray photoelectron spectroscopy (XPS) to observe valence energy and some orbital spectroscopy, such as In3d5/2, Sn3d5/2, Ols, and Cls. According to the experiment by 4-point probe measurement, the first 5 minutes of KrF excimer laser exposure in ITO sample has little effect in the resistance. Therefore, the present inventor only takes 10 minutes (Sample B), and 15 minutes (Sample C) as KrF excimer exposure time, and the one without any treatment (Sample C) for processing X-ray photoelectron spectroscopy experiment. From FIG. 3, it shows that the valence of surface Fermi level (EF) moves about 0.3 eV after 10 minutes of laser exposure time, and the valence of surface EF moves about 0.7 eV after 15 minutes of laser exposure time. According to FIG. 4, it can be found that the peak of Ols core level moves to the lower binding energy after laser exposure. The movement status for the valence of surface EF in FIG. 4 is coincident to the movement in FIG. 3. The movement for the valence of surface EF is almost equivalent to the increased energy bending value of the ITO surface, the increased thickness in the depletion layer of ITO surface, and the increased surface work function in ITO. These results are coincident to the experiments by 4-point probe. Further, Kim et al, use ultraviolet to expose ITO film. The light is chosen from mercury light which is under low pressure (wavelength is 185 nm). This experiment also has similar effect, which increases surface work function of ITO film.

In the present experiment, Kr excimer laser is used to expose ITO sample. In addition, X-ray photoelectron spectroscopy and 4-point probe are used to the research in the chemical status and the work function of ITO sample under laser exposure. The surface work function of ITO after laser exposure is increased 0.3˜0.7 Ev compared to the one before laser exposure. The experimental result confirms that ITO sample by laser exposure can increase its surface work function. This shows that the excimer laser exposure technique can be applicable to OLED manufacture. Further, it can increase the hole injection performance of the component, decrease the operational voltage of the component, and improve OLED component performance.

Besides to the above mentioned KrF excimer laser with 250 nm of wavelength, the type of the excimer laser used in the present invention can also be one of following lasers:
Ar₂ excimer laser with 126 nm of wavelength;
Kr₂ excimer laser with 146 nm of wavelength;
F₂ excimer laser with 157 nm of wavelength;
Xe₂ excimer laser with 172 nm of wavelength;
ArF excimer laser with wavelength at 190 nm;
XeF excimer laser with wavelength at 193 nm;
KrF excimer laser with wavelength at 250 nm; and
XeCl excimer laser with wavelength at 350 nm.

The method for increasing the work function of the indium-tin-oxide (ITO) film under the excimer laser exposure treatment in the present invention can be applicable to OLED manufacture. It can use excimer laser to expose the positive of ITO film for the surface treatment, increase the surface work function of ITO film, and achieve the hole injection performance. Besides, the present invention can be used in solar batteries, different display panels (include LCD panel, OLED panel), and other optical-related component manufacture.

While the invention has been described with reference to preferred embodiments, it will be understood by those skilled in the art that various changes may be made and equivalents may be substituted for members thereof without departing from the scope of the invention. In addition, many modifications may be made to adapt a particular situation to the teachings of the invention without departing from the essential scope thereof. For example, it should be obvious that the slider guide may be formed as a monolithic piece or may be an assembly having two or more parts. Therefore it is intended that the invention not be limited to the particular embodiment disclosed as the best mode contemplated for carrying out this invention, but that the invention will include all embodiments falling within the scope of the appended claims.

What is claimed is:

1. A method for increasing the work function of the ITO film under an excimer laser exposure treatment, wherein said excimer laser exposing to the ITO film can increase its surface work function; said range of the excimer laser energy is between tens and hundreds mJ/cm²; said frequency range is between zero and hundred Hz; and said exposure time is between five minutes to tens hours.

2. A method according to claim 1, wherein said ITO film has a thickness in the range between a few nanometers and hundreds nanometers.

3. A method according to claim 1, the type of said excimer laser can be one of following lasers:
Ar₂ excimer laser with 126 nm of wavelength;
Kr₂ excimer laser with 146 nm of wavelength;
F₂ excimer laser with 157 nm of wavelength;
Xe₂ excimer laser with 172 nm of wavelength;
ArF excimer laser with 190 nm of wavelength;
XeF excimer laser with 193 nm of wavelength;
KrF excimer laser with 250 nm of wavelength; and
XeCl excimer laser with 350 nm of wavelength.

4. A method according to claim 1, the surface of said ITO film is cleaned before the excimer laser exposure.

5. A method according to claim 4, wherein said surface cleaning process is that ITO is deposited in acetone, and cleaned by water-jacket ultrasonic vibration for three minutes; said ITO is deposited in the deionized water, and cleaned by water-jacket ultrasonic vibration for three minutes; and said ITO is dried by nitrogen gun.
